(19) United States
(12) Patent Application Publication
(10) Pub. No.: US 2025/0096738 A1
(43) Pub. Date: Mar. 20, 2025

(54) POWER AMPLIFIER WITH ANALOG PREDISTORTION

(71) Applicant: Qorvo US, Inc., Greensboro, NC (US)

(72) Inventors: Baker Scott, San Jose, CA (US); George Maxim, Saratoga, CA (US); Stephen James Franck, Felton, CA (US); Christopher T. Brown, Sunnyvale, CA (US); Nadim Khlat, Cugnaux (FR)

(21) Appl. No.: 18/729,618

(22) PCT Filed: Feb. 1, 2023
(86) PCT No.: PCT/US2023/061741

§ 371 Date: Jul. 17, 2024

Related U.S. Application Data
(60) Provisional application No. 63/267,553, filed on Feb. 4, 2022.

(51) Int. Cl. H03F 1/32; H03F 1/02; H03F 3/195; H03F 3/24

(52) U.S. Cl. CPC H03F 1/3282; H03F 1/0266; H03F 1/0272; H03F 3/195; H03F 3/245; H03F 2200/451; H03F 2201/3227; H03F 2201/3233

(57) ABSTRACT

A power amplifier with analog predistortion is disclosed. In one aspect, a signal in the transmission chain is sampled to determine if an amplitude distortion (expansion or compression) is present. Information about the sampled signal is provided to a control circuit, which uses an analog predistortion circuit to inject a correction signal into the transmission chain so as to offset or compensate for the amplitude distortion. In an exemplary aspect, the analog predistortion circuit adjusts a bias signal provided to the power amplifier. This detection and adjustment may be done in the front end of the transmission chain so as to avoid reliance on a baseband processor. Use of such analog predistortion helps maintain desired linear operation over the large bandwidths of emerging wireless communication standards.

### PRIORITY CLAIM

The present application claims priority to U.S. Provisional Patent Application Ser. No. 63/267,553 filed on Feb. 4, 2022 and entitled “POWER AMPLIFIER WITH ANALOG PREDISTORTION,” the contents of which is incorporated herein by reference in its entirety.

### BACKGROUND

### I. Field of the Disclosure

The technology of the disclosure relates generally to power amplifiers and, more particularly, to helping to provide linear performance for power amplifiers through analog predistortion.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to increase bandwidth available for communication. Responsive to such pressure, newer wireless communication standards such as the Fifth Generation-New Radio (5G-NR) have changed the operating frequency into the gigahertz range, which in turn requires operation by transmission chains within the mobile communication device across correspondingly wide modulation bandwidths. Having large bandwidth requirements in the transmission chain places a burden on the elements of the transmission chain and particularly the power amplifiers within the transmission chain to operate linearly over the large bandwidth. This burden provides opportunities for innovation.

### SUMMARY

Aspects disclosed in the detailed description include a power amplifier with analog predistortion. In an exemplary aspect, a signal in a transmission chain is sampled to determine if an amplitude distortion (expansion or compression) is present. Information about the sampled signal is provided to a control circuit, which uses an analog predistortion circuit to inject a correction signal into the transmission chain so as to offset or compensate for the amplitude distortion. In an exemplary aspect, the analog predistortion circuit adjusts a bias signal provided to the power amplifier. This detection and adjustment may be done in the front end of the transmission chain so as to avoid reliance on a baseband processor. Use of such analog predistortion helps maintain desired linear operation over the large bandwidths of emerging wireless communication standards.

In this regard in one aspect, a transmission chain is disclosed. The transmission chain comprises a power amplifier stage. The transmission chain also comprises a bias circuit coupled to the power amplifier stage. The transmission chain also comprises a detection and alignment circuit coupled to the power amplifier stage and configured to detect a power level of a signal associated with the power amplifier stage. The transmission chain also comprises an amplitude modulation (AM)-to-amplitude modulation (AM) (AM-AM) predistortion circuit coupled to the detection and alignment circuit and the bias circuit. The AM-AM predistortion circuit is configured to provide a correction signal to the bias circuit based on detected characteristics from the detection and alignment circuit.

### BRIEF DESCRIPTION OF THE DRAWINGS

FIG. 1A is a block diagram of a transceiver having an exemplary transmission chain which may benefit from the present disclosure;

FIG. 1B is a phase versus power graph showing how phase may distort as power is increased in the transmission chain;

FIG. 2 is a block diagram of an exemplary transmission chain having an analog predistortion circuit used to offset phase distortion in the transmission chain;

FIG. 3 is a block diagram expanding the power amplifier of FIG. 2, showing where signal detection may occur;

FIG. 4 is a block diagram showing how multiple analog predistortion circuits may be used for a series of power amplifiers in a transmission chain;

FIG. 5 illustrates how different portions of an open-loop analog predistortion circuit may be implemented between a digital circuit and an analog circuit;

FIG. 6 is a phase versus power graph showing how the phase distortion may vary between a phase advancement and a phase delay across the power range;

FIG. 7 is a block diagram showing how multiple analog predistortion circuits may be used to provide piecewise phase adjustments;

FIG. 8 is a graph showing how a varactor's capacitance may change as a function of voltage or power, illustrating the suitability of use of varactors in an analog predistortion circuit;

FIG. 9 is a block diagram showing how the varactor of FIG. 8 may be implemented in an analog predistortion circuit;

FIG. 10 is a block diagram showing how N-type field effect transistors (FETs) (NFETs) may be used as varactors in an analog predistortion circuit;

FIG. 11 is a block diagram of an alternate arrangement of NFET varactors used in an analog predistortion circuit;

FIG. 12 is a graph of amplitude-to-amplitude gain as a function of activity by the analog predistortion circuit compared to a graph of the amplitude-to-phase behavior as a function of the analog predistortion circuit showing how the functions are essentially orthogonal;

FIG. 13 is a block diagram of an exemplary transmission chain having an output-sensing analog predistortion circuit used to offset amplitude distortion in the transmission chain;

FIG. 14 is a block diagram of an exemplary transmission chain having an input-sensing analog predistortion circuit used to offset amplitude distortion in the transmission chain;

FIG. 15 is a block diagram of an exemplary transmission chain having an interstage-sensing analog predistortion circuit used to offset amplitude distortion in the transmission chain;

FIG. 16 is a block diagram of an exemplary transmission chain having multiple analog predistortion circuits with different sensing points used to offset amplitude distortion in the transmission chain;

FIGS. 17A-17C illustrate power versus amplitude distortion graphs showing exemplary possible distortion characteristics for which correction may be applied;

FIG. 18 is a block diagram of an exemplary transmission chain having multiple sensing circuits and multiple analog predistortion circuits used to offset complexly-shaped amplitude distortion profiles such as those shown in FIGS. 17A-17C;

FIG. 19 is a block diagram of a hybrid transmission chain where some elements are implemented in a complementary metal oxide semiconductor (CMOS) die and some elements are implemented in a III-V periodic material type die;

FIG. 20 is a block diagram of a transmission chain with a predistortion circuit that may control a bias for a single gain stage of the power amplifier or multiple gain stages;

FIG. 21 is a transmission chain showing details of an exemplary bias circuit that may provide predistortion according to an aspect of the present disclosure; and

FIG. 22 is a transmission chain showing details of an alternate exemplary bias circuit that may provide predistortion according to an aspect of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include a power amplifier with analog predistortion. In an exemplary aspect, a signal in a transmission chain is sampled to determine if an amplitude distortion (expansion or compression) is present. Information about the sampled signal is provided to a control circuit, which uses an analog predistortion circuit to inject a correction signal into the transmission chain so as to offset or compensate for the amplitude distortion. In an exemplary aspect, the analog predistortion circuit adjusts a bias signal provided to the power amplifier. This detection and adjustment may be done in the front end of the transmission chain so as to avoid reliance on a baseband processor. Use of such analog predistortion helps maintain desired linear operation over the large bandwidths of emerging wireless communication standards.

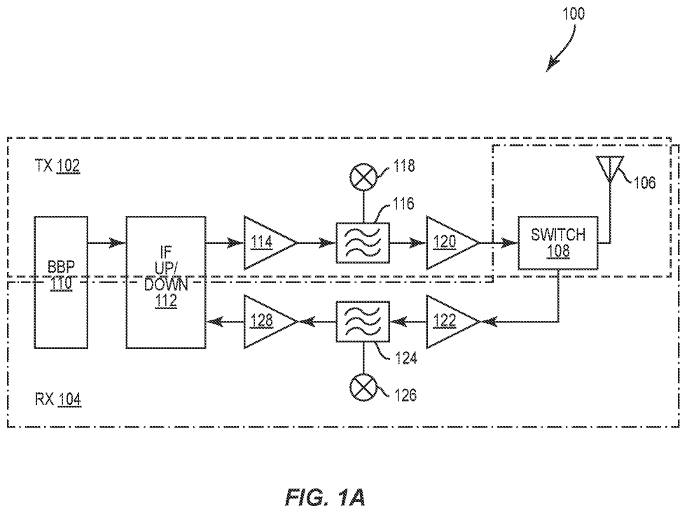

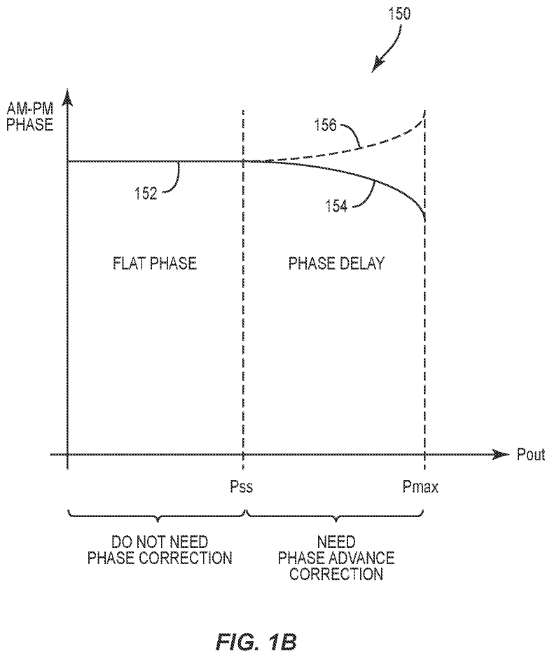

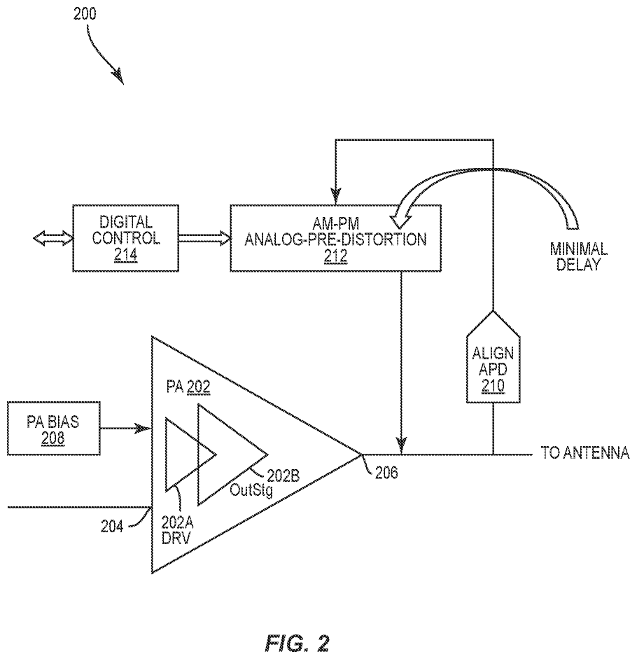

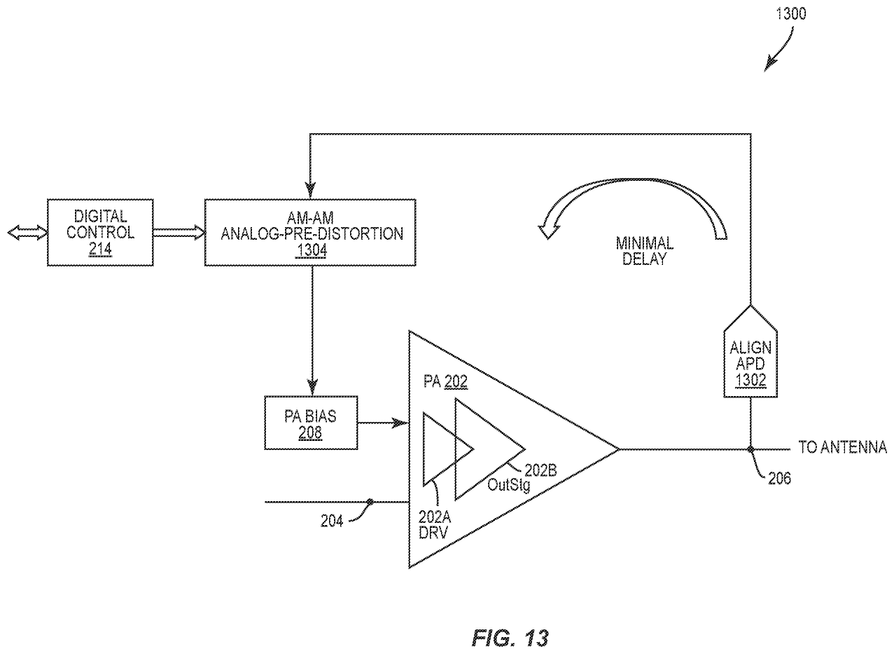

Before addressing exemplary aspects of the present disclosure, a brief overview of a transceiver and possible sources of phase distortion that negatively impacts performance are provided with reference to FIGS. 1A and 1B. A discussion of predistortion as it relates to a phase distortion begins below with reference to FIG. 2. A discussion of exemplary aspects of the present disclosure begins below with reference to FIG. 13.

In this regard, FIG. 1A illustrates a transceiver 100 having a transmission chain 102 and a receiver chain 104 that share an antenna 106 and a switch 108. Additional common elements may include a baseband processor (BBP) 110 and/or an intermediate frequency (IF) processor 112. Signals to be transmitted are generated in the BBP 110 and passed to the IF processor 112, which upconverts the baseband frequency to an IF signal. The IF signal may be amplified by a preamplifier stage 114. The amplified IF signal may be filtered by a filter stage 116, which may also interoperate with an oscillator 118 to upconvert to a radio frequency (RF) signal. The filter stage 116 may apply additional filtering to the RF signal. The RF signal may then be amplified by a power amplifier stage 120, which may include a driver stage, an output stage, and/or an intermediate stage (not shown). The amplified RF signal may be passed to the switch 108 for transmission through the antenna 106. In an exemplary aspect, the switch 108 may be a duplexer or the like.

The antenna 106 may also receive RF signals. Such received signals are passed to the switch 108, which passes the received RF signals to a low noise amplifier (LNA) 122. The amplified signals are passed to a filter stage 124, which filters the received signal and interoperates with an oscillator 126 to downcovert the RF signal to an IF signal. The oscillator 126 may be the same as the oscillator 118. The filter stage 124 may filter the IF signal as well before passing the IF signal to an IF amplifier 128, which amplifies the IF signal before passing the amplified IF signal to the IF processor 112, which downconverts the signal to a baseband signal, which is processed by the BBP 110.

It should be appreciated that other combinations of elements may also be used to form a transmission chain and the elements in FIG. 1A are intended to illustrate a context for the present disclosure and not limit the claimed aspects. For example, a transmission chain may eliminate the use of IF signals without departing from the scope of the present disclosure. As another readily contemplated aspect, the IF processor 112 and the BBP 110 may be combined.

To provide desired operation, the elements of the transmission chain 102 should have a generally linear operation profile. However, many of these elements are not linear over large frequency ranges. With the advent of large bandwidth operating ranges in new generations of cellular standards, providing linearity over the entire frequency range and/or power range is increasingly difficult. This difficulty is particularly true for power amplifiers, which may introduce phase distortion over a portion of the power range as illustrated in FIG. 1B. Specifically, FIG. 1B illustrates graph 150, which shows the overall phase characteristic with exemplary phase distortion at large power levels. That is, at power levels below Pss, the phase is relatively flat as shown by line segment 152. However, at power levels above Pss, extending up to Pmax, the phase begins to delay as shown by line segment 154. Line segment 156 shows a needed correction to return to linear operation.

While some linearity may be provided by increasing current to the power amplifier to operate as a class-AB amplifier, this increased current use degrades overall efficiency of the power amplifier. Another option is the concept of digital predistortion. Such digital predistortion occurs in the BBP 110 and may require complex interoperation with the power amplifiers 114, 120. Alternatively, the BBP 110 may include extensive tables with various operating parameters and the desired predistortion values based on the numerous operating parameters. As the bandwidths in question become larger in new wireless standards, existing solutions become less effective and provide opportunities for innovation.

Exemplary aspects of the present disclosure contemplate analog predistortion of the phase using an open loop feedback circuit that minimizes delay between measuring the phase distortion and correction. A high-level block diagram of this solution is provided in FIG. 2. Additional details are provided in subsequent Figures.

With reference to FIG. 2, a transmission chain 200 is shown. Particularly, a power amplifier stage 202 is shown that amplifies an RF signal received at an input 204 before passing the amplified signal to an antenna (not shown) from an output 206. It should be appreciated that input 204 and output 206 may be considered nodes, although such terminology is not generally used for these elements in the present disclosure. While input 204 and output 206 are shown as single ended, it should be appreciated that these could be differential without departing from the scope of the present disclosure. For ease in explanation, subsequent examples will also use single-ended architectures with the understanding that differential or quadrature could be used as needed or desired.

The power amplifier stage 202 may include one or more sub-stages such as a driver stage 202A and an output stage 202B. The power amplifier stage 202 receives a bias signal from a bias circuit 208. A detection and alignment circuit 210 may be associated with the power amplifier stage 202 to detect a phase of signals. The detection and alignment circuit 210 may communicate with an amplitude modulation (AM)-to-phase modulation (PM) (AM-PM) predistortion circuit 212. The AM-PM predistortion circuit 212 is expected to be an analog circuit and thus may be represented by an acronym APD. The AM-PM predistortion circuit 212 may interoperate with a digital controller 214 as explained in greater detail below. Based on communication from the detection and alignment circuit 210, the AM-PM predistortion circuit 212 injects a correction signal to compensate for phase distortion. As explained in greater detail below, the correction signal may be a phase advance correction signal or a phase delay correction signal. Collectively, the detection and alignment circuit 210 with the AM-PM predistortion circuit 212 form an open-loop feed forward analog predistortion phase correction block that will work with a bias circuit to set a quiescent point of the AM-PM predistortion circuit 212 such that either a phase advance or a phase delay correction is generated.

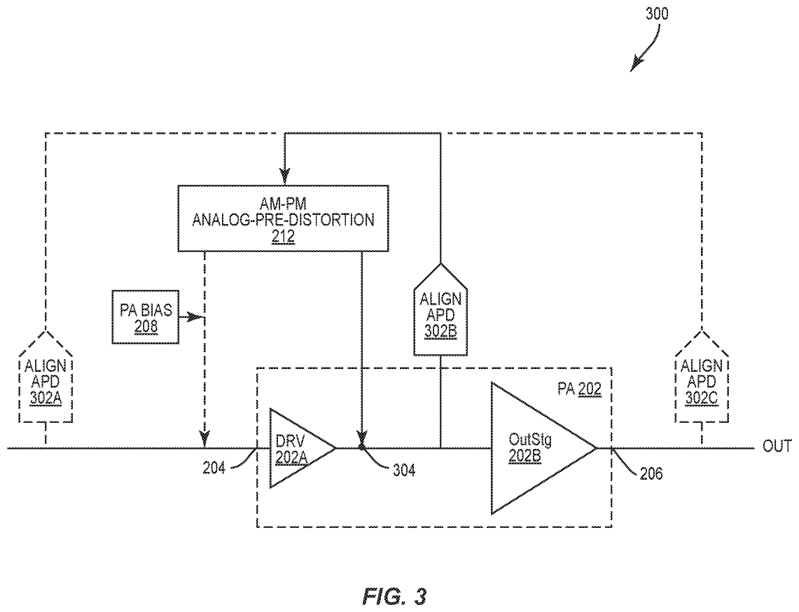

Depending on the structure of the power amplifier stage 202, the precise placement of the detection and alignment circuit 210 and the place where the correction signal is injected may be varied as better seen in FIG. 3. In this regard, FIG. 3 illustrates a transmission chain 300 where the power amplifier stage 202 has been expanded to show more explicitly the driver stage 202A and the output stage 202B. In a first exemplary aspect, a detection and alignment circuit 302A may be positioned at the input 204. In a second exemplary aspect, a detection and alignment circuit 302B may be positioned at a node 304 between the driver stage 202A and the output stage 202B. In a third exemplary aspect, a detection and alignment circuit 303C may be positioned at the output 206.

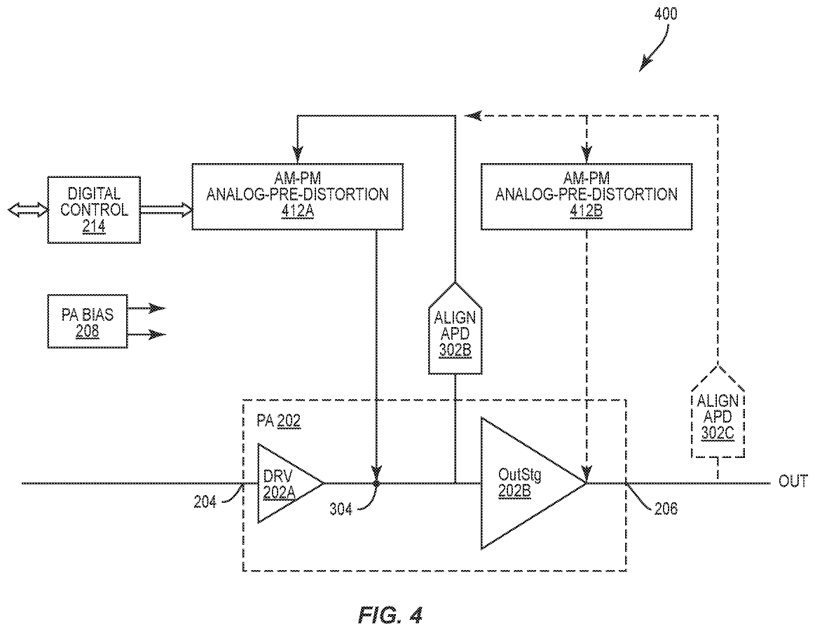

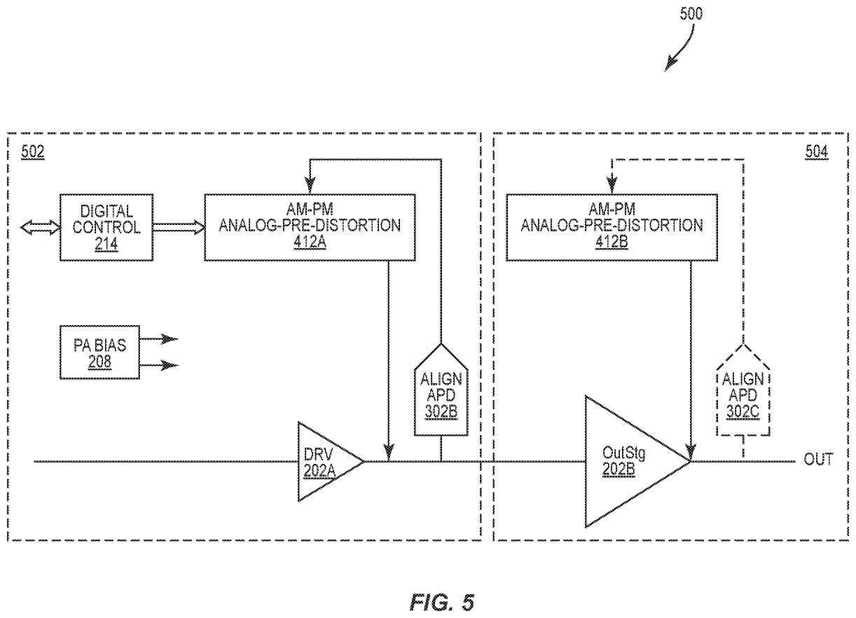

While any of the three positions (204, 206, 304) noted may be used, and in some cases, multiple positions may be used concurrently (as explained below with reference to, for example, FIG. 4 or 5), it is expected that the position at the node 304 will perform better than the other aspects. Positioning the detection and alignment circuit 302A at the input 204 may result in too little swing in the power to provide enough differentiation on which to make correction decisions. In contrast, positioning the detection and alignment circuit 302C at the output 206 may have too much power present, which results in excessive power consumption in the AM-PM predistortion circuit 212. Accordingly, positioning the detection and alignment circuit 302B at the node 304 may have some advantages over the other two locations.

In addition to placement of the detection and alignment circuit 302A, 302B, 302C at various positions, injection of the correction signal may occur at the input 204 or at the node 304. While it is conceptually possible to correct at the output 206 (as suggested, for example, in FIG. 2), such correction is likely to consume excess power and be less efficient than at the input 204 or the node 304.

As noted above, it is possible that there may be multiple sensing positions, possibly working in conjunction with multiple predistortion circuits. For example, a transmission chain 400, illustrated in FIG. 4, may include a first AM-PM predistortion circuit 412A working with a detection and alignment circuit 302B at the node 304. A second detection and alignment circuit 302C at the output 206 may provide additional information to the first AM-PM predistortion circuit 412A and/or provide the additional information to an optional second AM-PM predistortion circuit 412B. The second AM-PM predistortion circuit 412B may inject the correction signal at the output 206. In this arrangement, coarse adjustments may be made by the first AM-PM predistortion circuit 412A and fine adjustments made by the second AM-PM predistortion circuit 412B. While not shown in FIG. 4, the detection and alignment circuit 302A may be associated with a third AM-PM predistortion circuit and inject a correction signal at the input 204. In any case where there are multiple correction signals being injected, there may be communication between the AM-PM predistortion circuits so that the correction signals do not fight each other.

FIG. 5 illustrates a transmission chain 500 which is provided to show that exemplary aspects of the present disclosure may work in hybrid systems where part of the transmission chain is digital and part of the transmission chain is analog. Specifically, a first portion 502 of the transmission chain 500 may be implemented in a complementary metal oxide semiconductor (CMOS) (bulk or silicon on insulator) die while a second portion 504 of the transmission chain 500 may be implemented in a gallium arsenide (GaAs) die. In an exemplary aspect, the driver stage 202A, the bias circuit 208, the digital controller 214, the detection and alignment circuit 302B, and the first AM-PM predistortion circuit 412A are provided in the first portion 502, while the output stage 202B is in the second portion 504. Optionally, a second detection and alignment circuit 302C and a second AM-PM predistortion circuit 412B may be present in the second portion 504. Note that there is no digital control for the second AM-PM predistortion circuit 412B in this implementation. Note further that the lack of a digital controller for the second AM-PM predistortion circuit 412B makes it harder to control and correspondingly more difficult to deploy and as such, it is possible that the detection and alignment circuit 302C and the second AM-PM predistortion circuit 412B may be omitted.

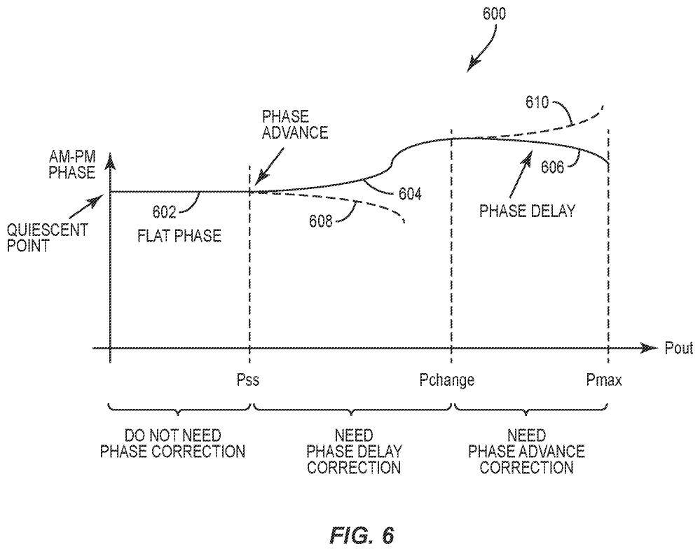

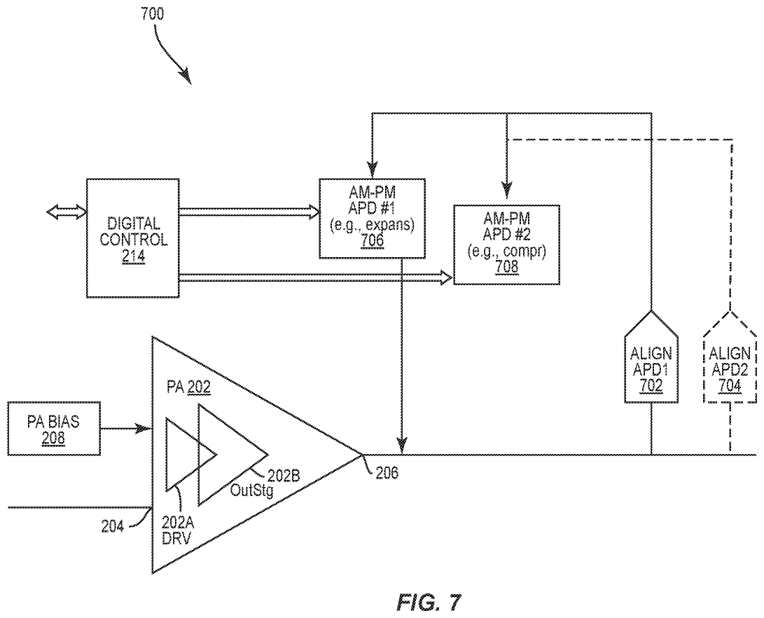

While FIG. 1B contemplates a single sort of inflection in the phase, the real world is not necessarily so neat and there may instances where, as power changes, the phase distortion may change from a phase advance to a phase delay or vice versa. The former possibility is illustrated in FIG. 6. Specifically, a graph 600 shows with a line segment 602 how a phase may be linear below power Pss, but between power Pss and power Pchange a phase advance is present as shown by line segment 604. Finally, above power Pchange, a phase delay may be present as shown by line segment 606. The corresponding required predistortions are shown by line segments 608 and 610. Providing compensation in such instances where compensation is needed in both advance and delay directions may be done with two predistortion circuits as better illustrated in FIG. 7.

In this regard, FIG. 7 shows a transmission chain 700 with a first detection and alignment circuit 702 and a second detection and alignment circuit 704. The first detection and alignment circuit 702 is coupled to a first AM-PM predistortion circuit 706, and the second detection and alignment circuit 704 is coupled to a second AM-PM predistortion circuit 708. While FIG. 7 shows the detection and alignment circuits 702, 704 positioned at the output 206, it should be appreciated that they may be positioned at the input 204, between the stages of the power amplifier stage 202, or at the output 206.

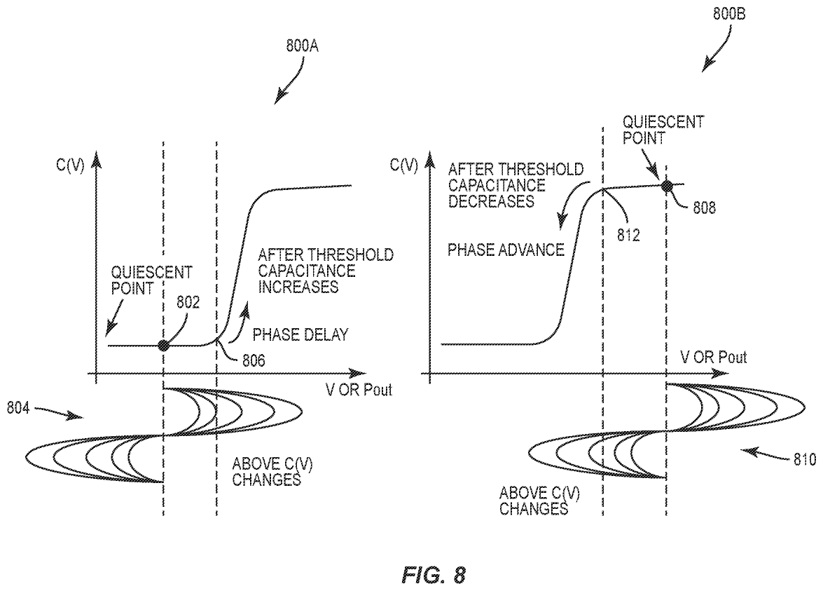

While a variety of options exist to implement any of the AM-PM predistortion circuits of the present disclosure, a device having a non-linear capacitance that varies as a function of voltage provides a ready solution. Further, the device may have a nonlinear variation with a flat portion and a monotonic increase (or a monotonic decrease) in capacitance. A varactor is one such device. FIG. 8 shows graphs 800A and 800B of the capacitance as a function of voltage.

In particular, graph 800A shows a varactor having a first quiescent point 802 at a relatively low capacitance. As the voltage changes around the quiescent point 802 (shown generally at 804), the capacitance will remain flat or, if a threshold 806 is exceeded, capacitance increases, which allows a phase delay correction signal to be generated.

In contrast, as shown in graph 800B, the varactor may have a relatively high quiescent point 808. As the voltage changes around the quiescent point 808 (shown generally at 810), the capacitance will remain flat or, if a threshold 812 is passed, capacitance decreases, which allows a phase advance correction signal to be generated. The quiescent point may be set by the digital controller 214.

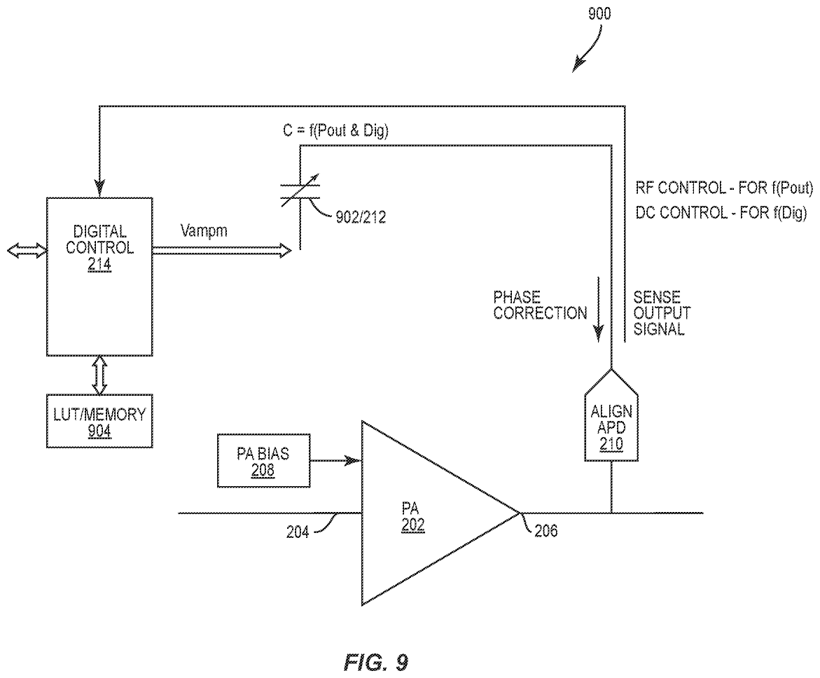

FIG. 9 shows a transmission chain 900 having a varactor 902 being used as an AM-PM predistortion circuit 212. The detection and alignment circuit 210 reports a sensed output signal to the digital controller 214, which may use a look-up table (LUT) stored in memory 904 to determine a voltage signal (Vampm) to send to the varactor 902 so that a phase correction signal may be provided to the power amplifier stage 202. While FIG. 9 shows the detection and alignment circuit 210 positioned at the output 206, it should be appreciated that it may be positioned at the input 204, between the stages of the power amplifier stage 202, or at the output 206.

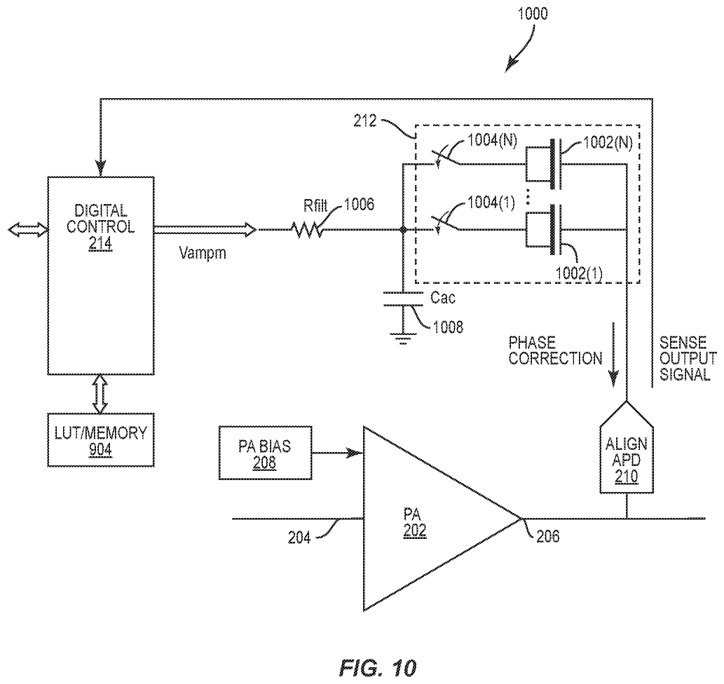

One way to implement a varactor is through an N-type field effect transistor (FET) (NFET). Further, it should be appreciated that multiple varactors may be used and switched on or off depending on a mode of operation. For example, depending on 4G or 5G may change a varactor size. Likewise, changing between a power level, frequency, or other parameter may be optimized by changing varactors. A simplified switching system using NFET varactors is illustrated in FIG. 10.

In this regard, FIG. 10 shows a transmission chain 1000 that has a plurality of varactors 1002 (1)-1002(N) operating as the AM-PM predistortion circuit 212. Each varactor 1002 (1)-1002(N) may have an associated switch 1004(1)-1004(N) that allows the digital controller 214 to turn on and off a given varactor 1002(1)-1002(N). Alternatively, some varactors 1002(1)-1002(N) may always be active. Additional control over the varactors 1002(1)-1002(N) may be provided by a filter resistor 1006 and a capacitor 1008. Selective use of varactors in this fashion allows different varactors to provide phase delays and others to provide phase advancements. Combining the varactors 1002(1)-1002(N) in various combinations may allow the precise phase adjustment to be selected. The digital controller 214 may consult the LUT in the memory 904 relative to the signal from the detection and alignment circuit 210 and select appropriate commands to open and close the switches 1004(1)-1004(N) as needed to meet the desired adjustment. While FIG. 10 shows the detection and alignment circuit 210 positioned at the output 206, it should be appreciated that it may be positioned at input 204, between the stages of the power amplifier stage 202, or at the output 206.

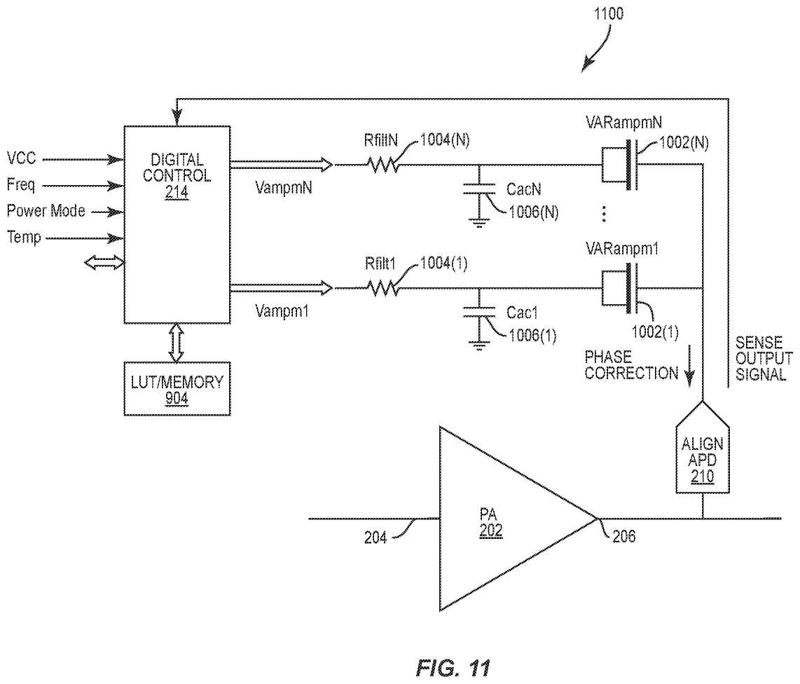

Instead of using switches 1004(1)-1004(N), the varactors may be individually controlled as better seen in FIG. 11. In this regard, FIG. 11 shows a transmission chain 1100 that has independent varactors 1102(1)-1102(N). Each varactor 1102(1)-1102(N) has an associated filter resistor 1104(1)-1104(N) and capacitor 1106(1)-1106(N). The digital controller 214 may generate individual control signals (Vampm1-VampmN). If the control signal is low, the varactor 1102(1)-1102(N) does not turn on, and does not contribute to the correction signal. Selective use of varactors in this fashion allows different varactors to provide phase delays and others to provide phase advancements. Combining the varactors in various combinations may allow the precise phase adjustment to be selected. The digital controller 214 may consult the LUT in the memory 904 relative to the signal from the detection and alignment circuit 210 and select appropriate commands to activate or deactivate different varactors 1102(1)-1102(N) as needed to meet the desired adjustment. While FIG. 11 shows the detection and alignment circuit 210 positioned at the output 206, it should be appreciated that it may be positioned at input 204, between the stages of the power amplifier stage 202, or at the output 206.

The digital controller 214 may use not just the signal from the detection and alignment circuit 210, but may also consider other parameters such as Vcc, frequency, power mode, temperature, cellular mode (e.g., 4G vs. 5G), or the like.

Note also that a given varactor in any of the above aspects may be turned off by moving the quiescent point so that changes in the voltage do not trigger the thresholds 806, 812.

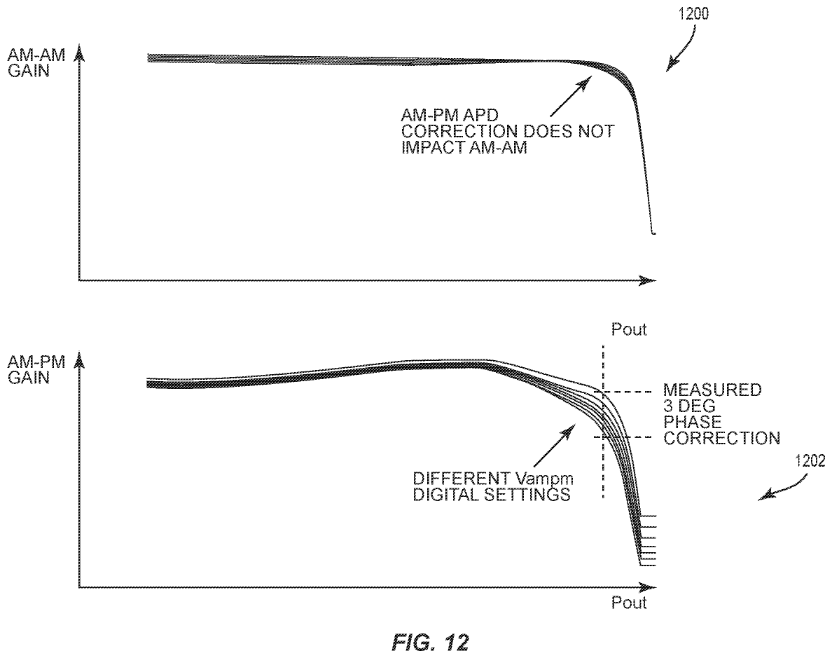

It should further be appreciated that AM-PM correction according to exemplary aspects of the present disclosure does not necessarily affect other parameters or metrics of the power amplifier stage 202. Thus, as shown in FIG. 12, a first graph 1200 shows that AM-PM predistortion does not affect AM-AM attributes while the second graph 1202 shows how the same AM-PM predistortion affects the output phase. Such orthogonality will be relevant in any AM-AM predistortion schemes such as those explored below.

In addition to the phase distortion issues, there may be instances where there is amplitude distortion. Again, historical solutions may provide predistortion solutions in the baseband processor. Such solutions may be impractical or expensive in emerging technologies. Accordingly, exemplary aspects of the present disclosure contemplate providing an open-loop feed-forward analog predistortion AM-AM technique to provide amplitude linearization. Many of the concepts of the AM-AM techniques are similar to those used in the AM-PM techniques discussed above.

In this regard, FIG. 13 illustrates a transmission chain 1300 that has a power amplifier stage 202 with an input 204 and an output 206. The transmission chain 1300 includes a power sensing circuit, which may be a detection and alignment circuit 1302. The detection and alignment circuit 1302 is in the transmission chain 1300 at output 206 and communicates information about a sensed power level to an AM-AM predistortion circuit 1304. The AM-AM predistortion circuit 1304 may be coupled to a digital controller 214 and a bias circuit 208. Signals from the AM-AM predistortion circuit 1304 may cause the bias circuit 208 to adjust a bias signal provided to the power amplifier 202.

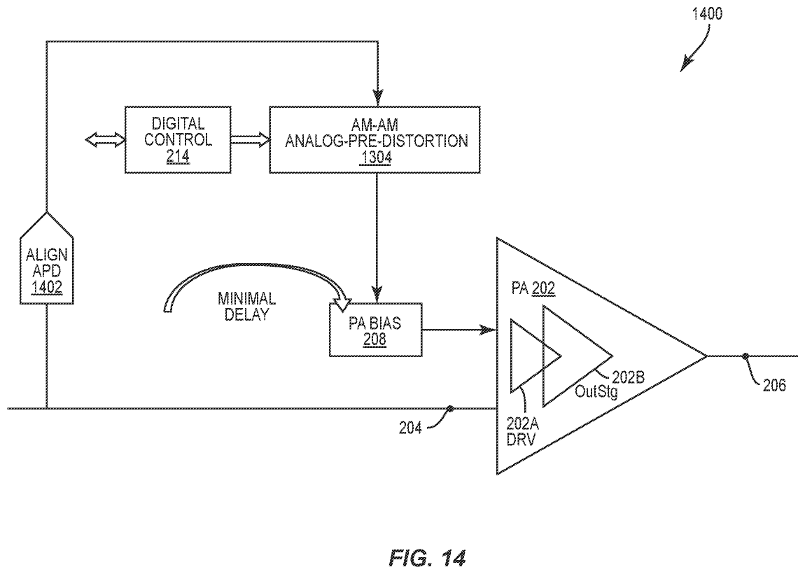

Instead of positioning the detection and alignment circuit at the output 206, the detection and alignment circuit may be positioned at the input 204 as better illustrated in FIG. 14, where a transmission chain 1400 includes a detection and alignment circuit 1402 that performs the measurement at the input 204.

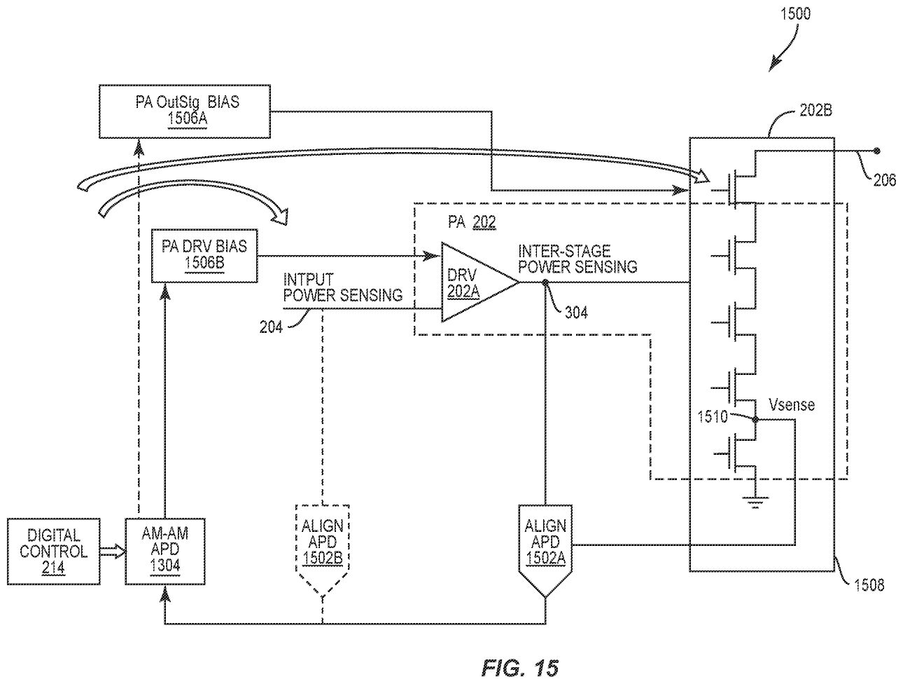

Still further, there may be instances where the detection and alignment circuit may be positioned at the node 304 and/or there may be multiple detection and alignment circuits as better seen in transmission chain 1500 of FIG. 15. The transmission chain 1500 may have a first detection and alignment circuit 1502A at the node 304 and an optional second detection and alignment circuit 1502B at the input 204. The detection and alignment circuits 1502A, 1502B may send information about sensed power to a single AM-AM predistortion circuit 1304 (as illustrated), or there may be multiple respective predistortion circuits (not shown). The predistortion circuit(s) 1304 may control multiple bias circuits 1506A, 1506B so as to control the distortion applied at each stage 202A, 202B independently. Still further, the first detection and alignment circuit 1502A may receive information from within a transistor stack 1508 that forms the output stage 202B such as at node 1510.

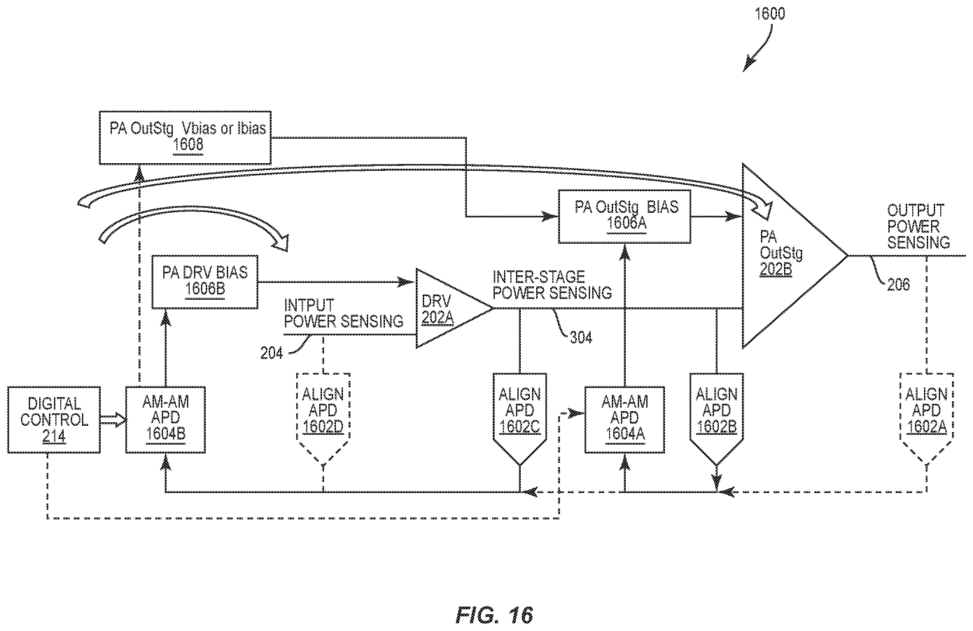

FIG. 16 provides a block diagram of a transmission chain 1600 having a variety of open-loop feed-forward loops to provide AM-AM predistortion according to exemplary aspects of the present disclosure. In particular, the transmission chain 1600 may have a first detection and alignment circuit 1602A at the output 206. The first detection and alignment circuit 1602A may be associated with a first predistortion circuit 1604A. A second detection and alignment circuit 1602B may also be associated with the first predistortion circuit 1604A. The first predistortion circuit 1604A may control an output stage bias circuit 1606A.

A third detection and alignment circuit 1602C may be associated with a second predistortion circuit 1604B and take measurements at the node 304. A fourth detection and alignment circuit 1602D may also be associated with the second predistortion circuit 1604B and take measurements at the input 204. The second predistortion circuit 1604B may control a driver stage bias circuit 1606B and/or also provide input to the output stage bias circuit 1606A through an intermediate bias circuit 1608. The digital controller 214 may communicate with both predistortion circuits 1604A and 1604B to coordinate predistortion signals so that the two predistortion circuits 1604A and 1604B do not cause overcorrection and conflicting instructions.

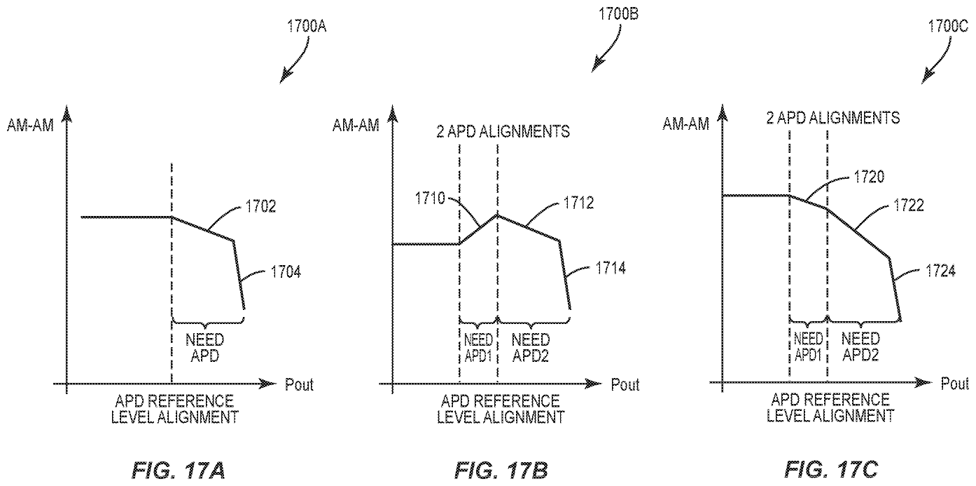

It should be appreciated that much like phase distortion may have phase delays and phase advancements for which predistortion is used to compensate, so too may there be a variety of amplitude distortions as better illustrated in FIGS. 17A-17C. For example, in FIG. 17A, a graph 1700A of power versus AM distortion shows that there may be a first amplitude compression 1702 having a first slope followed by a harder amplitude compression 1704 having a harder or more severe slope. The first amplitude compression 1702 may be overcome with predistortion while the severe slope of the harder amplitude compression 1704 may exceed the ability of a predistortion to compensate.

Similarly, FIG. 17B shows a graph 1700B having the same axes, but a first segment is an amplitude expansion 1710 having a first slope and a second segment is an amplitude compression 1712 having a second slope. Finally, a third segment is a hard compression 1714. Different predistortion circuits may be used to provide different sorts of compensation or correction signals to the bias circuits.

Likewise, FIG. 17C shows a graph 1700C having the same axes, but with two relatively soft compressions. That is, a first segment 1720 has a first slope for which compensation may be applied. A second segment 1722 has a second slope for which compensation may also be applied. However, a third segment 1724 has a hard compression that exceeds compensation capabilities.

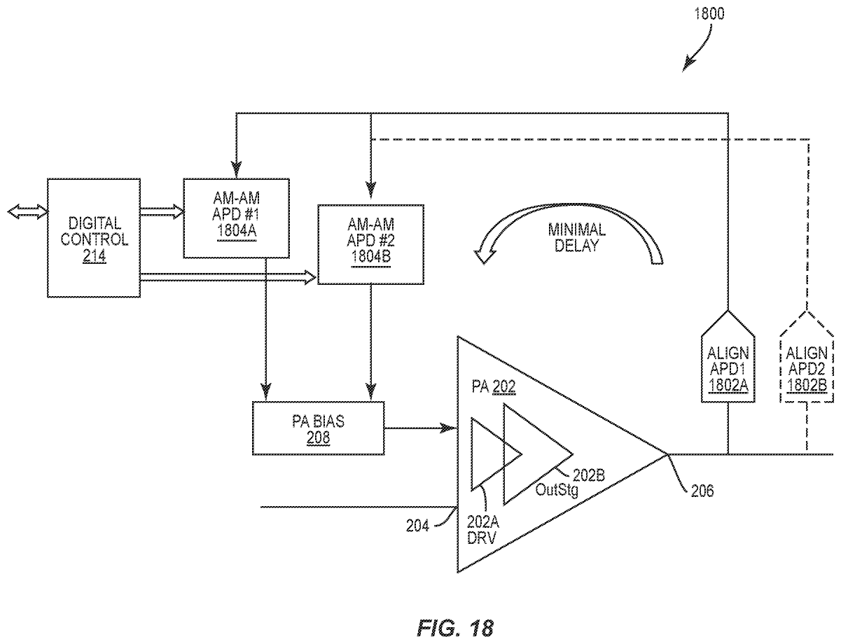

To provide the different compensation signals to the bias circuits, a transmission chain may use multiple loops such that one loop works to correct amplitude compression and another loop works to correct amplitude expansion. In this regard, FIG. 18 illustrates a transmission chain 1800 having a first detection and alignment circuit 1802A that works with a first predistortion circuit 1804A to form a first loop and provide a correction signal to a bias circuit 208. In an exemplary aspect, this first loop may provide correction to compressed amplitudes. A second detection and alignment circuit 1802B works with a second predistortion circuit 1804B to form a second loop and provide a second correction signal to the bias circuit 208. The digital controller 214 may interoperate with the predistortion circuits 1804A, 1804B to make sure they do not conflict. While shown as being positioned at the output 206, it should be appreciated that other positions for the detection and alignment circuits 1802A, 1802B may be provided.

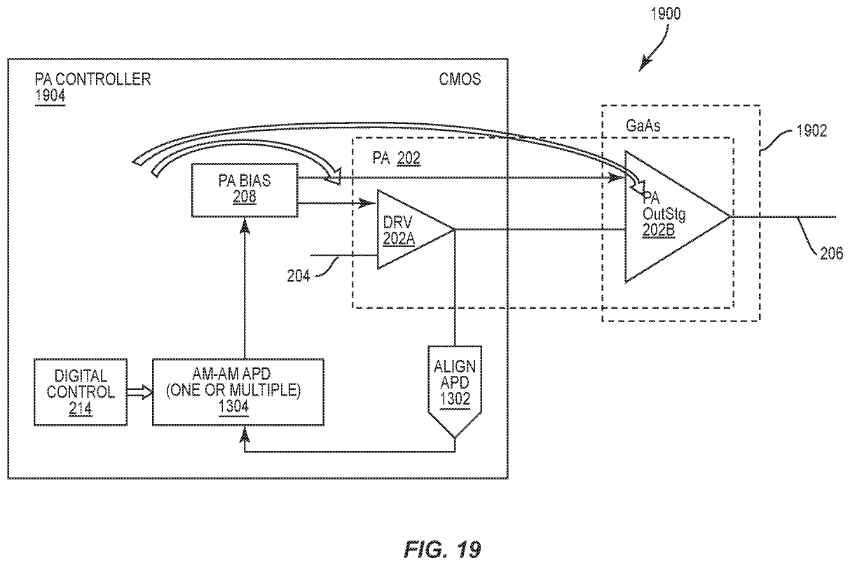

As with the phase distortion circuitry, it is possible to have portions of the open-loop feed-forward amplitude predistortion loop be provided in different dice. Specifically, as illustrated in FIG. 19, a transmission chain 1900 may have a first die 1902. The output stage 202B of the power amplifier stage 202 may be implemented in the first die 1902 and the first die 1902 may be a GaAs die. Additionally, the transmission chain 1900 may have a second die 1904. The second die 1904 may include the bias circuit 208, the driver stage 202A, the digital controller 214, the detection and alignment circuit 1302, and the predistortion circuit 1304. The second die 1904 may be a CMOS die. The bias circuit 208 may have separate circuitry for the driver stage 202A and the output stage 202B, but both may be present in the second die 1904.

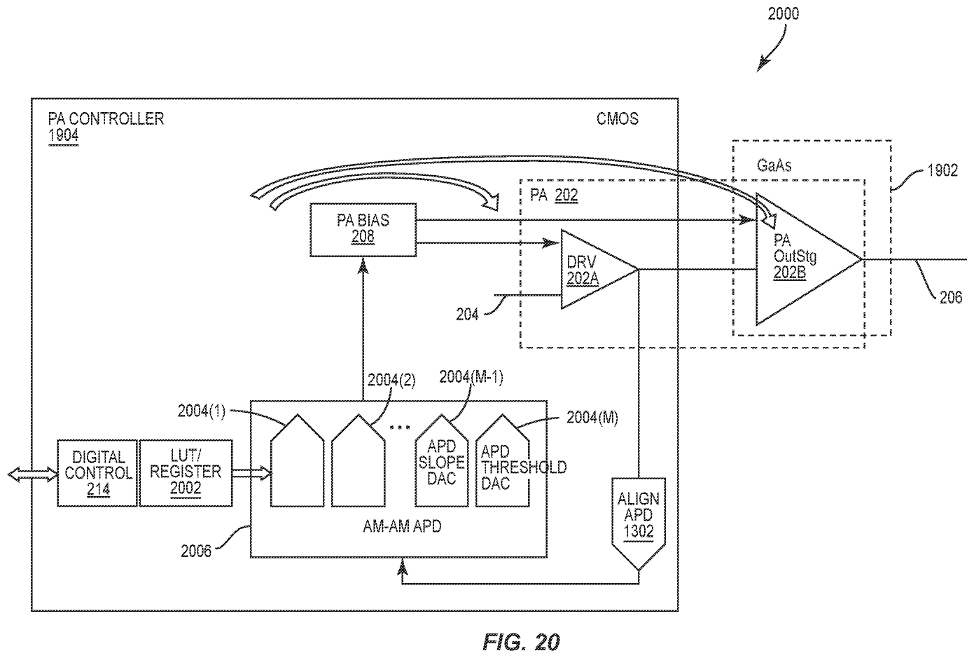

The predistortion circuit may be implemented to control only the bias of a single gain stage (e.g., the driver stage 202A or the output stage 202B) or the predistortion circuit may control all stages. In this regard, FIG. 20 illustrates a transmission chain 2000 which may be a two-die architecture like the transmission chain 1900 of FIG. 19. In the transmission chain 2000, the digital controller 214 may work with a LUT 2002 that is stored in a register or other memory device. Based on values in the LUT 2002, the digital controller 214 may set values for one or more digital-to-analog converters (DACs) 2004(1)-2004(M) in a predistortion circuit 2006. The values stored in the DACs 2004(1)-2004(M) may be slope and/or threshold values corresponding to the inflection points such as those shown in FIGS. 17A-17C and the slopes of the various line segments. These values may be used to set bias current or bias voltages produced by the bias circuit 208 or the like.

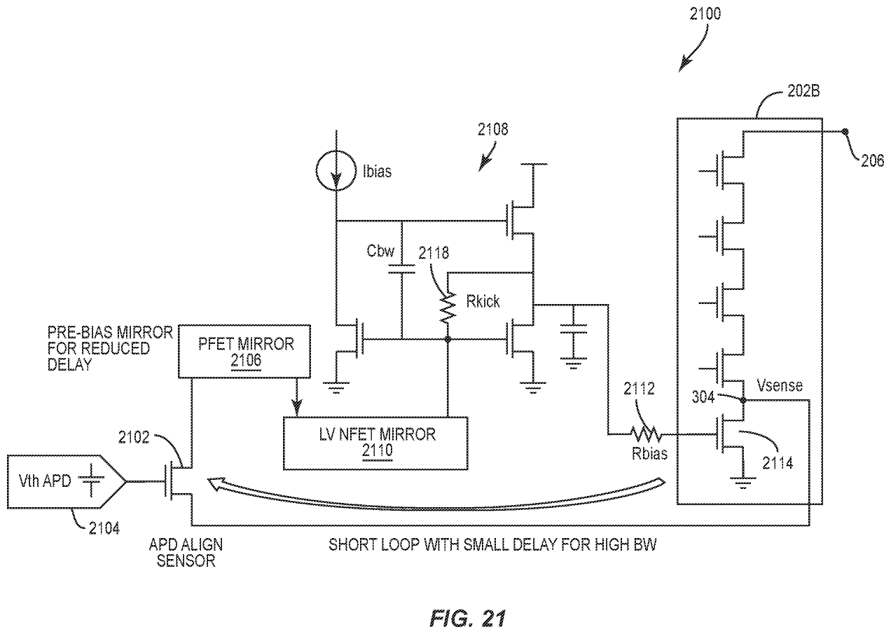

Additional details about an exemplary bias circuit are provided with reference to FIG. 21. In this regard, FIG. 21 shows a transmission chain 2100 where a detection and alignment circuit 2102 is a FET that activates based on a threshold voltage 2104. A P-type FET (PFET) current mirror 2106 works with a Wilson current mirror 2108 and an NFET current mirror 2110 to provide a bias signal through a bias resistor 2112 to a bottom stage 2114 of a cascode stack within the output stage 202B.

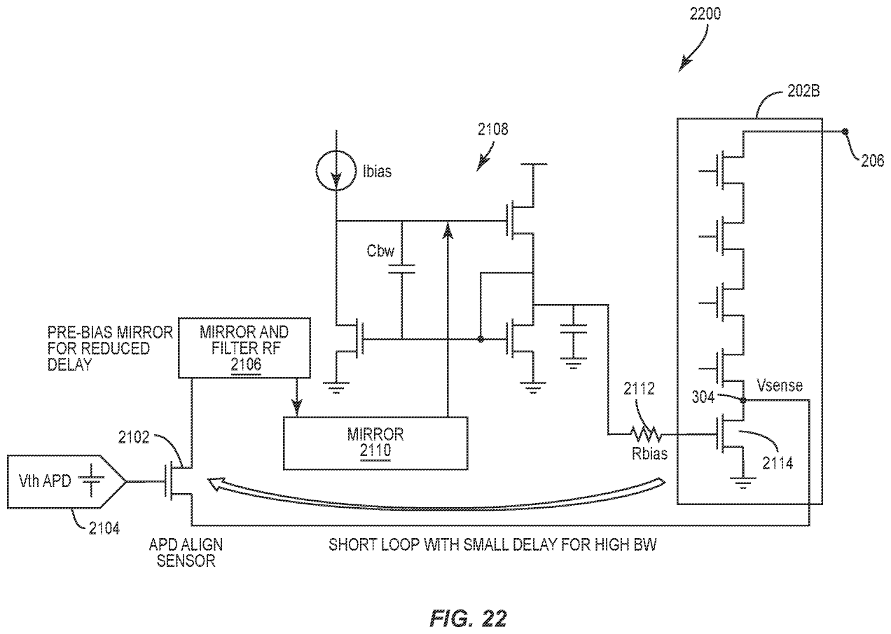

A kicker resistor 2118 may introduce noise and thus may be eliminated as shown in a transmission chain 2200 of FIG. 22. Removal of the kicker resistor 2118 causes the NFET mirror 2110 to couple to the Wilson current mirror 2108 at a different point, but otherwise, the transmission chain 2200 is substantially similar to the transmission chain 2100 of FIG. 21.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

1. A transmission chain comprising:
a power amplifier stage;
a bias circuit coupled to the power amplifier stage;
a detection and alignment circuit coupled to the power amplifier stage and configured to detect a power level of a signal associated with the power amplifier stage; and
an amplitude modulation (AM)-to-amplitude modulation (AM) (AM-AM) predistortion circuit coupled to the detection and alignment circuit and the bias circuit, the AM-AM predistortion circuit configured to provide a correction signal to the bias circuit based on detected characteristics from the detection and alignment circuit thereby forming an open loop feedback circuit that minimizes delay between measuring distortion and correction.

2. The transmission chain of claim 1, wherein the power amplifier stage comprises:
an input;
a driver stage coupled to the input;
an output stage coupled to the driver stage with a node therebetween; and
an output coupled to the output stage.

3. The transmission chain of claim 2, wherein the detection and alignment circuit is coupled to the input.

4. The transmission chain of claim 2, wherein the detection and alignment circuit is coupled to the output.

5. The transmission chain of claim 2, wherein the detection and alignment circuit is coupled to the node between the driver stage and the output stage.

6. The transmission chain of claim 2, further comprising:
a second bias circuit, wherein the bias circuit is coupled to the driver stage and the second bias circuit is coupled to the output stage;
a second detection and alignment circuit coupled to the node between the driver stage and the output stage; and
a second AM-AM predistortion circuit coupled to the second detection and alignment circuit, the second AM-AM predistortion circuit configured to provide a second correction signal to the second bias circuit based on signals from the second detection and alignment circuit.

7. The transmission chain of claim 1, further comprising a digital control circuit coupled to the AM-AM predistortion circuit and configured to control the AM-AM predistortion circuit based on one or more of a frequency, power mode, temperature, and cellular mode.

8-9. (canceled)

10. The transmission chain of claim 1, further comprising a digital controller coupled to the AM-AM predistortion circuit and configured to control the AM-AM predistortion circuit.

11. The transmission chain of claim 1, further comprising a digital controller coupled to the bias circuit and configured to control the bias circuit.

12. The transmission chain of claim 11, wherein the digital controller comprises a look-up table (LUT).

13. The transmission chain of claim 12, wherein the digital controller comprises at least one digital-to-analog converter (DAC).

14. The transmission chain of claim 1, wherein the bias circuit comprises at least one current mirror.

15. The transmission chain of claim 1, wherein the correction signal causes the bias circuit to output a bias signal to expand an output signal from the power amplifier stage.

16. The transmission chain of claim 1, wherein the correction signal causes the bias circuit to output a bias signal to compress an output signal from the power amplifier stage.

17. The transmission chain of claim 1, wherein the power amplifier stage is single ended.

18. The transmission chain of claim 1, wherein the power amplifier stage is differential.
